(19) United States
(12) Patent Application Publication
(10) Pub. No.: US 2003/0163654 A1
(43) Pub. Date: Aug. 28, 2003

(54) System and method for efficient scheduling of memory

(76) Inventors: Eliel Louzoun, Jerusalem (IL); Israel Herscovich, Modin (IL)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/082,434

(22) Filed: Feb. 22, 2002

(51) Int. Cl. G11C 5/00

(52) U.S. Cl. 711/154; 711/5; 711/156; 711/104; 711/168; 711/169

(57) ABSTRACT

A method, system, and apparatus to schedule commands based on a status information of a plurality of memory banks.

### DESCRIPTION OF THE RELATED ART

A Dynamic Random Access Memory, DRAM, is a typical memory to store information for computers and computing systems, such as, personal digital assistants and cellular phones. DRAMs contain a memory cell array having a plurality of individual memory cells; each memory cell is coupled to one of a plurality of sense amplifiers, bit lines, and word lines. The memory cell array is arranged as a matrix of rows and columns, and the matrix is further subdivided into a number of banks.

One type of DRAM is a synchronous dynamic random access memory (SDRAM) that allows for synchronous operation with a processor. Specific types of SDRAM are a single data rate (SDR) SDRAM and a double data rate (DDR) SDRAM. The SDR SDRAM receives a single bit of data, in each bit of the databus, for each system clock pulse, typically, on either the rising or falling edge of the system clock pulse. In contrast, DDR SDRAM receives two bits of data, in each bit of the databus, for each system clock pulse, typically, one bit on the rising and one bit on the falling edge of the system clock pulse.

Memory devices, including SDRAMS, receive read and write commands via a memory bus coupled to a processor or a memory controller. If the memory bus needs to transition from a read to write command, or vice-versa, the memory bus requires several clock cycles to accommodate the new type of command, commonly referred to as a “turn-around”. Thus, the performance of the memory device suffers because it is idle and is waiting for the next command during the turn-around of the memory bus.

One typical solution is a round robin between the memory banks for read commands followed by a round robin between the memory banks for write commands. However, the round robin solution is inflexible. For example, if one of the memory banks is skipped because of the absence of read or write commands, the round robin solution is inadequate to select the next type of command or to select the next memory bank.

### BRIEF DESCRIPTION OF THE SEVERAL VIEWS OF THE DRAWINGS

Subject matter is particularly pointed out and distinctly claimed in the concluding portion of the specification. The claimed subject matter, however, both as to organization and method of operation, together with objects, features, and advantages thereof, may best be understood by reference to the following detailed description when read with the accompanying drawings in which:

FIG. 1 is a schematic diagram of a computing system in accordance with one embodiment.

FIG. 2 is a flowchart of a method in accordance with one embodiment.

### DETAILED DESCRIPTION OF THE INVENTION

A system and method for efficient scheduling of commands to memory are described.

In the following description, for purposes of explanation, numerous details are set forth in order to provide a thorough understanding of the present invention. However, it will be apparent to one skilled in the art that these specific details are not required in order to practice the present invention.

An area of current technological development relates to achieving improved memory performance. As previously described, the performance of the memory device suffers because it is idle and is waiting for the new command during the turn-around of the memory bus. In contrast, a method and system that incorporates scheduling commands to the memory device based at least in part on status information of the memory banks results in improved performance of the memory device by minimizing the turn-around of the memory bus.

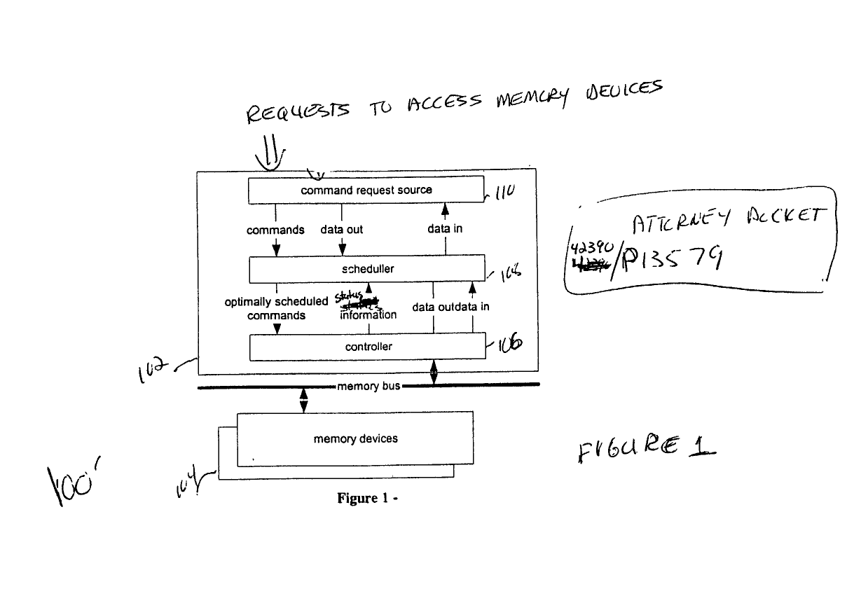

FIG. 1 is a schematic diagram of a computing system in accordance with one embodiment. In one embodiment, the system 100 includes, but is not limited to, a logic block 102 and a memory 104. In another embodiment, the system 100 includes, but is not limited to, a logic block 102 and a plurality of memory devices 104. In both embodiments, the memory device comprises a plurality of memory banks. Also, the memory devices are DRAM, SDRAM, DDR SDRAMS, or SDR SDRAMs. In one embodiment, the logic block 102 is a network switch. In another embodiment, the logic block is a memory controller. However, the claimed subject matter for the logic block is not limited to a network switch or memory controller. For example, logic block 102 may be a chipset, or integrated within a processor, or a portion of an application specific integrated circuit (ASIC).

In one embodiment, the logic block 102 includes, but is not limited to, a command request source 110, a scheduler 108, and a controller 106. The command request source receives requests that are pending commands to access the memory device or devices 104 from a processor, host, or memory controller. The command request source 110 generates commands, such as, read and write, for the memory based at least in part on the received requests. Also, the command request source forwards any data (data out) to be associated with the commands. The commands and data are forwarded from the command request source to the scheduler.

The scheduler 108 receives commands and data from the command request source and receives status information of the memory device's 104 banks via the controller 106. The scheduler 108 generates commands to the memory device in an optimal flow to improve the bandwidth of the memory bus and/or the performance of the memory device(s) 104. Specifically, the optimal flow is based at least in part on the commands from the command request source and the status information of the memory banks of the memory device(s) 104.

In one embodiment, the status information of the memory banks of the memory device(s) 104 indicates whether the memory bank is idle. In another embodiment, the status information indicates whether the memory bank is idle or will be idle before the command is forwarded from the scheduler to the controller. In both preceding embodiments, the status information is represented by a bit for each memory bank. However, the claimed subject matter for the status information is not limited to a single bit. For example, the status information may be a single bit that is part of a register containing several bits. Another example is the status information is two or more bits and is used to indicate whether the bank is idle and contains other status information, such as, the number of cycles until an idle condition, least recently used status, etc . . .

In yet another embodiment, the status information of the memory banks indicates whether the bank is idle or will be idle when the controller receives the command, which banks have a request for a write command, which banks have a request for a read command, the type of the previous command, which bank was accessed in the previous command, the maximum number of write commands still allowed, and the maximum number of read commands still allowed.

In yet another embodiment, the status information is based on a value that is stored in a register to indicate a predefined condition, such as, a value to compensate for pipeline delay cycles. For example, the value may be set to five, which is used to notify the logic block when a certain bank or banks will be idle in five cycles.

In one embodiment, the logic block 102 is utilized with a bank based queuing scheme to determine the specific bank to receive a command. For example, the claimed subject matter supports optimizing the scheduling of the commands as well as any bank based queuing scheme that allows for accessing the banks in an optimized way. For example, the logic 102 is coupled to a second logic to supervise and control the access of the banks. In another example, the logic 102 schedules commands and supervises and controls the access of the banks. In one embodiment, the bank based queuing scheme monitors the order of the banks to receive commands with a pointer.

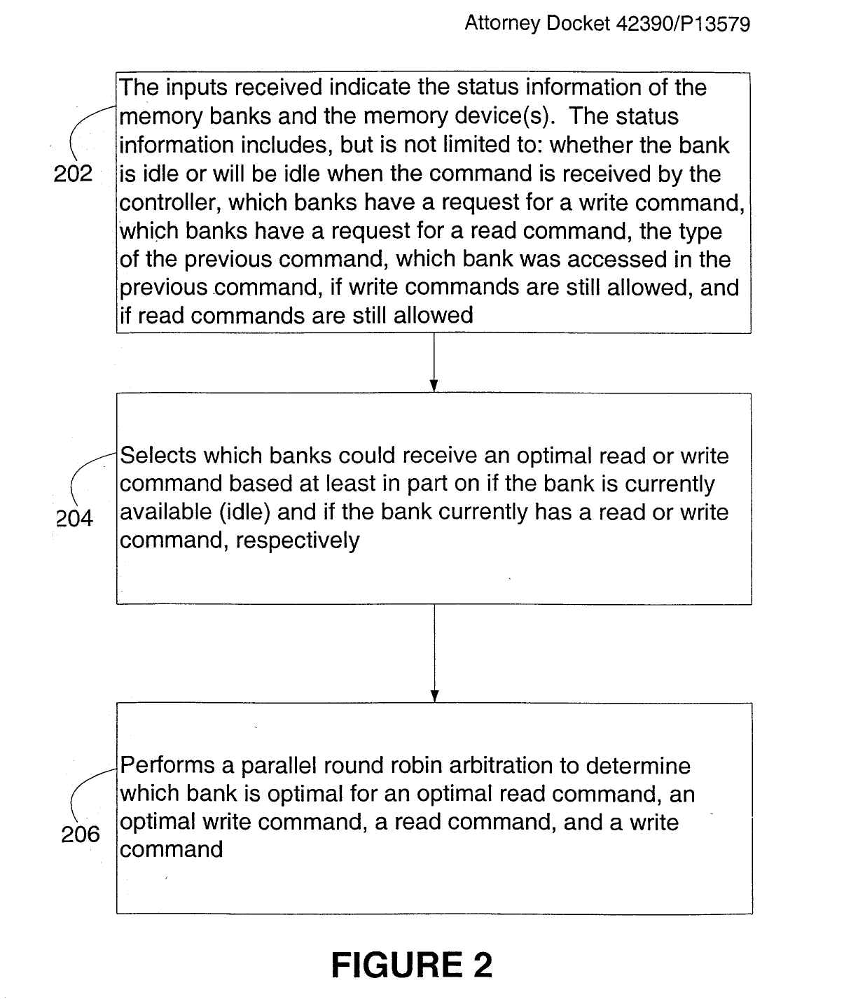

FIG. 2 is a flowchart of a method in accordance with one embodiment. The flowchart 200 illustrates an example of a method to generate commands in an optimal flow to be forwarded to the memory device(s) 104 via the controller 106 and memory bus depicted in FIG. 1. The optimal flow determines the sequence of commands, the type of commands, such as, read and write, and selection of the appropriate bank of the plurality of memory banks. In one embodiment, the flowchart is stored as software code. In another embodiment, the computing system described in connection with FIG. 1 executes the flowchart of FIG. 2.

A block 202, depicts the list of inputs the flowchart receives to determine the optimal flow of commands. The inputs received indicate the status information of the memory banks and the memory device(s). The status information includes, but is not limited to: whether the bank is idle or will be idle when the command is received by the controller, which banks have a request for a write command, which banks have a request for a read command, the type of the previous command transmitted via the memory bus, which bank was accessed in the previous command, if write commands are still allowed, and if read commands are still allowed. In one embodiment, a predetermined amount of write and read commands are stored in two counters and are decremented when a write or read command is issued, respectively.

In one embodiment, the status information is stored for a memory device with four banks. However, the claimed subject matter for the status information is not limited to four banks. For example, the claimed subject matter supports memory devices with different bank configurations by storing the appropriate number of bits, such as, eight bits for an eight-bank configuration. Also, for block 202, the claimed subject matter is not limited to the previously described inputs. For example, the status information for the memory bank may only include a subset of the inputs depicted in block 202. For example, the idle information may only include which banks are presently idle and ignore if the bank will be idle when the controller receives the command.

Alternatively, the status information may include more than the inputs depicted in block 202. For example, the status information may include priority information for certain types of commands to allow for faster execution. The priority information could be for a write command to reset the memory device because of a request by the processor.

A block 204, depicts the analysis of determining which banks could receive optimal commands based on the received inputs listed in block 202. The block 204 selects which banks could receive an optimal read or write command based at least in part on if the bank is currently available ) and if the bank currently has a read or write command, respectively. An optimal read command refers to if the bank is idle and the pending command is a read command. Thus, the read command is considered optimal because the bank is conditioned for another read command and there is no need to turn-around the memory bus from a read command. Alternatively, an optimal write command refers to if the bank is idle and the pending command is a write command. Thus, the write command is considered optimal because the bank is conditioned for another write command and there is no need to turn-around the memory bus from a write command.

A block 206, depicts selecting the optimal bank based at least in part on the selection of banks in block 204. The block 206 performs a parallel round robin arbitration to determine which bank is optimal for an optimal read command, an optimal write command, a read command, and a write command. Arbitration generally refers to deciding which requester receives access to a shared resource. Specifically, the round robin arbitration decides which bank receives access to the memory device. The arbitration is based at least in part on: if the bank is able to receive an optimal or non-optimal command; if the bank was accessed for the previous command; and the type of the previous command. Optimal commands were discussed in the previous paragraph. In contrast, a non-optimal command does not consider the status information of the memory banks.

In one embodiment, the parallel round robin arbitration determines if the previous command was a write or read command. In one embodiment, the parallel round robin arbitration is a nested analysis.

For example, when the previous command was a write command, the arbitration issues an optimal write command for the following conditions: if a bank is capable of performing an optimal write command, the number of executed write commands has not exceeded a predetermined amount as defined in the write counter, and the absence of any pending read commands. Otherwise, in the absence of the optimal write command, an optimal read command is issued if the conditions previously described for the optimal read command are present. However, in the absence of an optimal write and optimal read command, the arbitration analyzes whether the write or read commands will exceed a predetermined amount as defined by the two counters. For example, if the value of the counter for read commands is zero, then the next issued read command will exceed the allowable number of read commands. Thus, the arbitration issues a write command.

Conversely, when the previous command was a read command, the arbitration issues an optimal read command for the following conditions: if a bank is capable of performing an optimal read command, the number of executed read commands has not exceeded a predetermined amount as defined in the read counter, and the absence of any pending write commands. Otherwise, in the absence of the optimal read command, an optimal write command is issued if the conditions previously described for the optimal write command are present. However, in the absence of an optimal write and optimal read command, the arbitration analyzes whether the write or read commands will exceed a predetermined amount as defined by the two counters. For example, if the value of the counter for write commands is zero, then the next issued write command will exceed the allowable number of write commands. Thus, the arbitration issues a read command.

In one embodiment, the flowchart supports SDR and DDR SDRAMs. However, the claimed subject matter is not limited to SDR and DDR SDRAMs. For example, the claimed subject matter supports any memory device with banks that operate in parallel. Specifically, banks that operate in parallel are capable of independent operation with respect to other banks of the memory device. To illustrate, a memory device has four independent memory banks, bank 0, bank 1, bank 2, and bank 3. Since the memory banks operate in parallel, each memory bank is capable of executing a different command at substantially the same time.

Although the claimed subject matter has been described with reference to specific embodiments, this description is not meant to be construed in a limiting sense. Various modifications of the disclosed embodiment, as well as alternative embodiments of the claimed subject matter, will become apparent to persons skilled in the art upon reference to the description of the claimed subject matter. It is contemplated, therefore, that such modifications can be made without departing from the spirit or scope of the claimed subject matter as defined in the appended claims.

1. A method comprising:
receiving a plurality of commands to access at least one of a plurality of memory banks of a memory; and
scheduling the plurality of commands based at least in part on a status information of at least one of the plurality of memory banks.

2. The method of claim 1 wherein the memory is a synchronous dynamic random access memory.

3. The method of claim 1 wherein the status information based at least in part on an idle state of the plurality of memory banks with respect to a bank based queuing scheme.

4. The method of claim 1 wherein the status information is either an idle state of the plurality of memory banks.

5. The method of claim 1 wherein the status information is based at least in part on a type of a most recent command forwarded to the memory device via a memory bus.

6. The method of claim 1 wherein the plurality of commands are read and write commands.

7. A system comprising:
a processor; and
a logic, coupled to the processor and to at least one memory device with a plurality of memory banks, to receive commands to access the memory device
and to schedule the commands based at least in part on a status information of the plurality of memory banks.

8. The system of claim 7 wherein the commands are read and write commands.

9. The system of claim 7 wherein the wherein the status information is based at least in part on a type of most recent command forwarded to the memory device via a memory bus.

10. The system of claim 7 wherein the plurality of memory banks perform in parallel.

11. The system of claim 7 wherein the logic is a network switch or a memory controller.

12. The system of claim 7 wherein the status information is an idle state of the plurality of memory banks.

13. The system of claim 7 wherein the memory is a synchronous dynamic random access memory.

14. An apparatus comprising:
a first logic, coupled to at least one memory device with a plurality of memory banks, to receive commands to access the memory device; and
a second logic, coupled to the first logic, to schedule the received commands based at least in part on a status information of the plurality of memory banks.

15. The apparatus of claim 14 further comprising a third logic to forward the schedule of the received commands to the memory device via a memory bus.

16. The apparatus of claim 14 wherein the apparatus is either one of a network switch or memory controller.

17. The apparatus of claim 14 wherein the memory device is a synchronous dynamic random access memory.

18. The apparatus of claim 14 wherein the received commands are read and write commands.

19. The apparatus of claim 14 wherein the status information is based at least in part on a type of most recent command forwarded to the memory device via the memory bus.

20. The apparatus of claim 14 wherein the plurality of memory banks perform in parallel.

21. The apparatus of claim 14 wherein the status information is an idle state of the plurality of memory banks.

22. A method comprising:
receiving a plurality of commands to access at least one of a plurality of memory banks of a memory coupled to a memory bus;
scheduling the plurality of commands based at least in part on a status information of at least one of the plurality of memory banks; and
arbitrating between the commands to determine priority of access to the memory bus.

23. The method of claim 22 wherein the memory is a synchronous dynamic random access memory.

24. The method of claim 22 wherein the status information is an idle state of the plurality of memory banks.

25. The method of claim 22 wherein the plurality of memory banks perform in parallel.

26. The method of claim 22 wherein the status information is based at least in part on a type of a most recent command forwarded to the memory device via a memory bus.

27. The method of claim 22 wherein the plurality of commands are read and write commands.

28. An article comprising:
a storage medium having stored thereon instructions, that, when executed by a computing platform, result in forwarding a plurality of commands to a memory device by:
receiving the plurality of commands to access at least one of a plurality of memory banks of the memory device; and
scheduling the plurality of commands based at least in part on a status information of at least one of the plurality of memory banks.

29. The article of claim 28 wherein the memory is a synchronous dynamic random access memory.

30. The article of claim 28 wherein the status information is an idle state of the plurality of memory banks.

31. The article of claim 28 wherein the plurality of memory banks perform in parallel.

32. The article of claim 28 wherein the status information is based at least in part on a type of a most recent command forwarded to the memory device via a memory bus.

33. The article of claim 28 wherein the plurality of commands are read and write commands.
